(19) United States
(12) Patent Application Publication
(10) Pub. No.: US 2026/0007076 A1
(43) Pub. Date: Jan. 1, 2026

(54) STRUCTURE WITH MRAM AND INDUCTOR AND FABRICATING METHOD OF THE SAME

(71) Applicant: UNITED MICROELECTRONICS CORP., Hsin-Chu City (TW)

(72) Inventors: Da-Jun Lin, Kaohsiung City (TW); Bin-Siang Tsai, Changhua County (TW); Fu-Yu Tsai, Tainan City (TW)

(73) Assignee: UNITED MICROELECTRONICS CORP., Hsin-Chu City (TW)

(21) Appl. No.: 18/792,583

(22) Filed: Aug. 2, 2024

(30) Foreign Application Priority Data
Jun. 28, 2024 (CN) 202410855388.7

(51) Int. Cl. H10N 50/01; G11C 11/16; H10B 61/00; H10N 50/10; H10N 50/80

(52) U.S. Cl. CPC H10N 50/01; H10B 61/00; H10D 1/20; H10N 50/10; H10N 50/80; G11C 11/161

(57) ABSTRACT

A structure with an MRAM and an inductor includes a first dielectric layer. A second dielectric layer covers the first dielectric layer. Numerous second metal lines are embedded in the first dielectric layer. An MRAM is disposed between the second dielectric layer and the first dielectric layer. A magnetic core is disposed below the second dielectric layer and covers the second metal lines. The distance from the topmost surface of the magnetic core to the first dielectric layer is smaller than the distance from the topmost surface of the MRAM to the first dielectric layer. Numerous fourth metal lines are embedded in the second dielectric layer and disposed on the magnetic core. The fourth metal lines and the second metal lines are electrically connected through numerous first conductive plugs. The second metal lines, the fourth metal lines and the first conductive plugs form an inductor coil surrounding the magnetic core.

### BACKGROUND OF THE INVENTION

### 1. Field of the Invention

The present invention relates to a structure with a magnetoresistive random access memory (MRAM) and an inductor and a fabricating method of the same, and more particularly to a structure and a method which can reduce a thickness of the structure with an MRAM and an inductor.

### 2. Description of the Prior Art

Many modern day electronic devices contain electronic memory configured to store data. Electronic memory may be volatile memory or non-volatile memory. Volatile memory stores data only while it is powered, while non-volatile memory is able to store data even when power is removed. MRAM is one promising candidate for next generation non-volatile memory technology.

Currently, MRAMs are not integrated with inductors for radio frequency (RF) applications. Most inductors are off-chip inductors which are assembled with MRAMs through circuit boards. Therefore, the cost increases. If MRAMs and inductors can be integrated on a single process and a single chip, the integration can be greatly improved and the cost can be reduced.

### SUMMARY OF THE INVENTION

In view of this, the present invention provides a structure with an MRAM and an inductor and a fabricating method thereof to solve the above problems.

According to a preferred embodiment of the present invention, a structure with an MRAM and an inductor includes a first dielectric layer, wherein the first dielectric layer includes a memory region and an inductor region. A second dielectric layer covers the first dielectric layer. A first metal line is embedded in the memory region in the first dielectric layer. Numerous second metal lines are embedded in the inductor region of the first dielectric layer. An MRAM is disposed between the second dielectric layer and the first dielectric layer, and the MRAM is disposed in the memory region. A magnetic core is disposed below the second dielectric layer and covers the second metal lines, wherein material of the magnetic core is the same as material of the MRAM. A first distance is disposed between the topmost surface of the magnetic core and a top surface of the first dielectric layer, a second distance is disposed between the topmost surface of the MRAM and the top surface of the first dielectric layer, and the second distance is greater than the first distance. A third metal line is embedded in the second dielectric layer, wherein the third metal line is disposed on and contacts the MRAM. Numerous fourth metal lines are embedded in the second dielectric layer and are disposed on the magnetic core, wherein the fourth metal lines and the second metal lines are electrically connected through the first conductive plugs, the second metal lines, the fourth metal lines and the first conductive plugs form an inductor coil surrounding the magnetic core.

According to another preferred embodiment of the present invention, a fabricating method of a structure with an MRAM and an inductor includes providing a first dielectric layer, wherein the first dielectric layer includes a memory region and an inductor region, a first metal line is embedded in the memory region of the first dielectric layer, and numerous second metal lines are embedded in the inductor region of the first dielectric layer. Next, an etching stop layer and a first silicon oxide layer are formed sequentially to cover the memory region and the inductor region of the first dielectric layer. Then, the first silicon oxide layer located in the inductor region is completely removed. Later, an MRAM material layer is formed to cover and contact the first silicon oxide layer in the memory region and cover and contact the etching stop layer in the inductor region. Subsequently, the MRAM material layer is patterned to form an MRAM and a magnetic core, wherein the MRAM is disposed in the memory region and the magnetic core is disposed in the inductor region. After that, a second dielectric layer is formed to cover the memory region and the inductor region. Finally, a metal interconnection process is performed to form a third metal line, numerous first conductive plugs and numerous fourth metal lines, wherein the third metal line is embedded in the second dielectric layer, disposed on the MRAM and in contact with the MRAM, the fourth metal lines are embedded in the second dielectric layer and disposed on the magnetic core, the first conductive plugs are disposed between the fourth metal lines and the second metal lines, the fourth metal lines and the second metal lines are electrically connected through the first conductive plugs, and the second metal lines, the fourth metal lines and the first conductive plugs form an inductor coil surrounding the magnetic core.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 depict a fabricating method of a structure with a magnetoresistive random access memory (MRAM) and an inductor according to a preferred embodiment of the present invention, wherein:

FIG. 1 shows a dielectric layer including a memory region, a logic circuit region and an inductor region;

FIG. 2 is a fabricating stage following FIG. 1;

FIG. 3 is a fabricating stage following FIG. 2;

FIG. 4 is a fabricating stage following FIG. 3;

FIG. 5 is a fabricating stage following FIG. 4;

FIG. 6 is a fabricating stage following FIG. 5;

FIG. 7 is a fabricating stage following FIG. 6; and

FIG. 8 is a fabricating stage following FIG. 7.

FIG. 9 depicts sectional views taken along lines AA′, BB′ and CC′ in FIG. 8.

FIG. 10 depicts a sectional view taken along line DD′ in FIG. 8.

### DETAILED DESCRIPTION

FIG. 1 to FIG. 8 depict a fabricating method of a structure with a magnetoresistive random access memory (MRAM) and an inductor according to a preferred embodiment of the present invention.

As shown in FIG. 1, a first dielectric layer 10 is provided. The first dielectric layer 10 includes a memory region M, a logic circuit region L and an inductor region I. A first metal line 12a is embedded in the memory region M of the first dielectric layer 10. A sixth metal line 12f is embedded in the logic circuit region L of the first dielectric layer 10. Numerous second metal lines 12b are embedded in the inductor region I of the first dielectric layer 10. Then, an etching stop layer 14 and a first silicon oxide layer 16 are sequentially formed to cover the memory region M, the logic circuit region L and the inductor region I of the first dielectric layer 10. Later, the first silicon oxide layer 16 located in the inductor region I is completely removed. Now, only the etching stop layer 14 remains to cover the first dielectric layer 10 in the inductor region I. The first dielectric layer 10 is preferably tetraethoxysilane (TEOS), and the etching stop layer 14 is preferably nitrogen-doped silicon carbide (NDC).

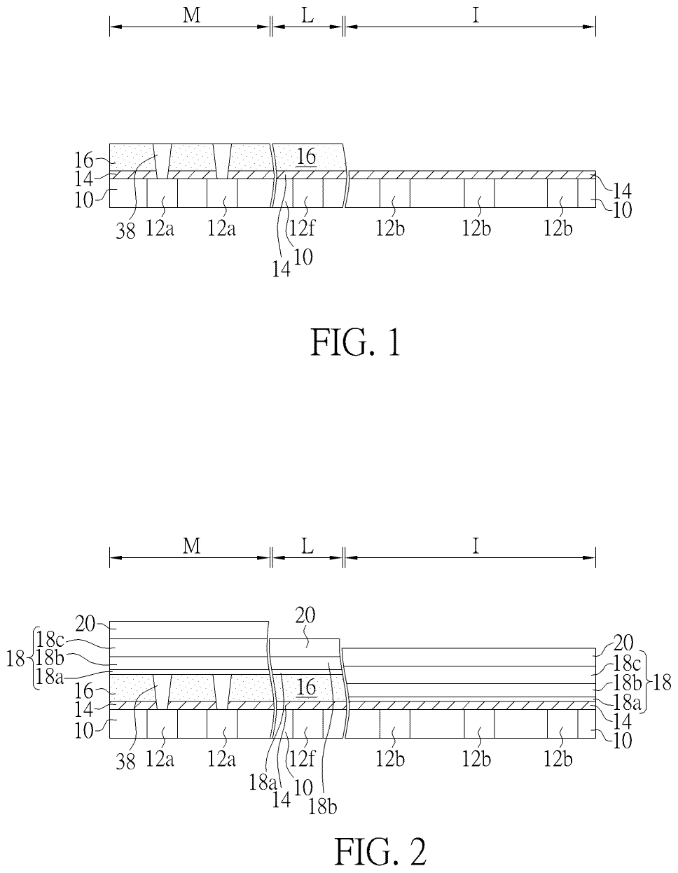

As shown in FIG. 2, an MRAM material layer 18 is formed to cover and contact the first silicon oxide layer 16 in the memory region M and the logic circuit region L, and to cover and contact the etching stop layer 14 in the inductor region I. The MRAM material layer 18 includes a first material layer 18a, a second material layer 18b and a third material layer 18c stacked from bottom to top. The first material layer 18a will serve as a bottom electrode of an MRAM, the second material layer 18b will serve as the magnetic tunneling junction (MTJ) of the MRAM, and the third material layer 18c will serve as the top electrode of the MRAM. Next, a mask layer 20 is formed to cover the MRAM material layer 18.

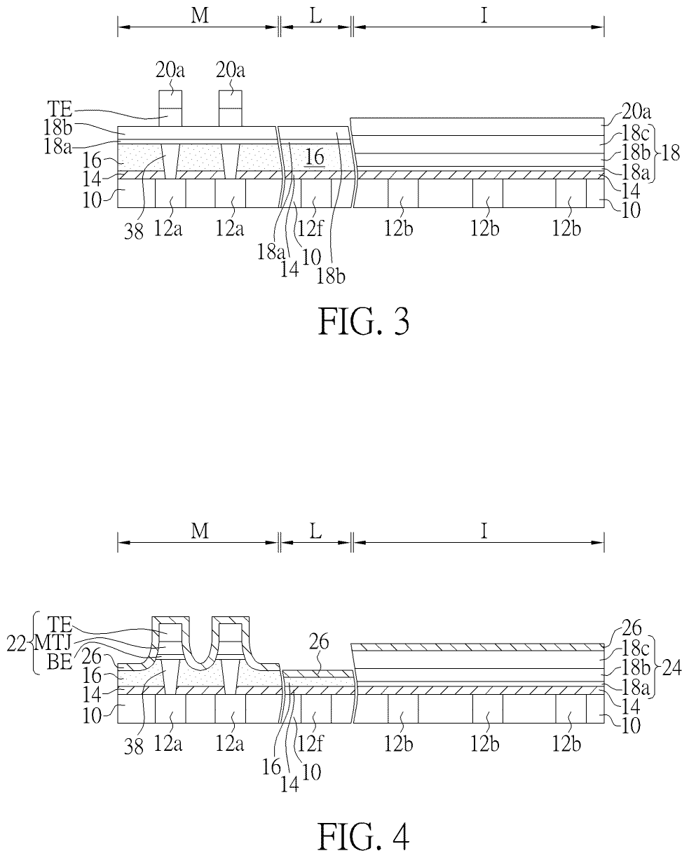

As shown in FIG. 3, the mask layer 20 is patterned to form a mask layer 20a. The mask layer 20a in the memory region M defines the location of the MRAM which will be formed afterwards. The mask layer 20 in the logic circuit region L is completely removed. The mask layer 20a in the inductor region I defines the position of the magnetic core of an inductor. Then, the third material layer 18c is etched by using the mask layer 20a as a mask. Now, the third material layer 18c in the logic circuit region L is completely removed. The third material layer 18c remaining in the memory region M serves as a top electrode TE. The third material layer 18c remaining in the inductor region I serves as part of a magnetic core.

As shown in FIG. 4, the second material layer 18b, the first material layer 18a and the first silicon oxide layer 16 are etched by taking the mask layer 20a and the third material layer 18c as masks. Now, the second material layer 18b remaining in the memory region M becomes a magnetic tunnel junction MTJ. The first material layer 18a remaining in the memory region M becomes a bottom electrode BE. The bottom electrode BE, the magnetic tunnel junction MTJ and the top electrode TE together form an MRAM 22. The second material layer 18b and the first material layer 18a in the logic circuit region L are completely removed. Besides, because there is no third material layer 18c serving as a mask in the logic circuit region L, the thickness of the first silicon oxide layer 16 in the logic circuit region L is etched more than the thickness of the first silicon oxide layer 16 in the memory region M. As a result, the topmost surface of the first silicon oxide layer 16 in the logic circuit region L is lower than the topmost surface of the first silicon oxide layer 16 in the memory region M. Moreover, the remaining second material layer 18b, the first material layer 18a and the third material layer 18c in the inductor region I together form a magnetic core 24. Then, a cap layer 26 is formed to cover the MRAM 22, the first silicon oxide layer 16 and the magnetic core 24. The cap layer 26 is preferably silicon nitride. The first material layer 18a and the third material layer 18c may respectively include titanium, titanium nitride, tantalum, or tantalum nitride. The second material layer 18b may include magnetic materials and insulating materials. The magnetic materials include CoFeB or PtMn. The insulating materials may be aluminum oxide or magnesium oxide.

It is noteworthy that because the first silicon oxide layer 16 in the inductor region I is completely removed in the step of FIG. 1, comparing with the memory region M, the space below the magnetic core 24 in the inductor region I is not occupied by the thickness of the first silicon oxide layer 16. In this way, the topmost surface of the magnetic core 24 will be lower than the topmost surface of the MRAM 22.

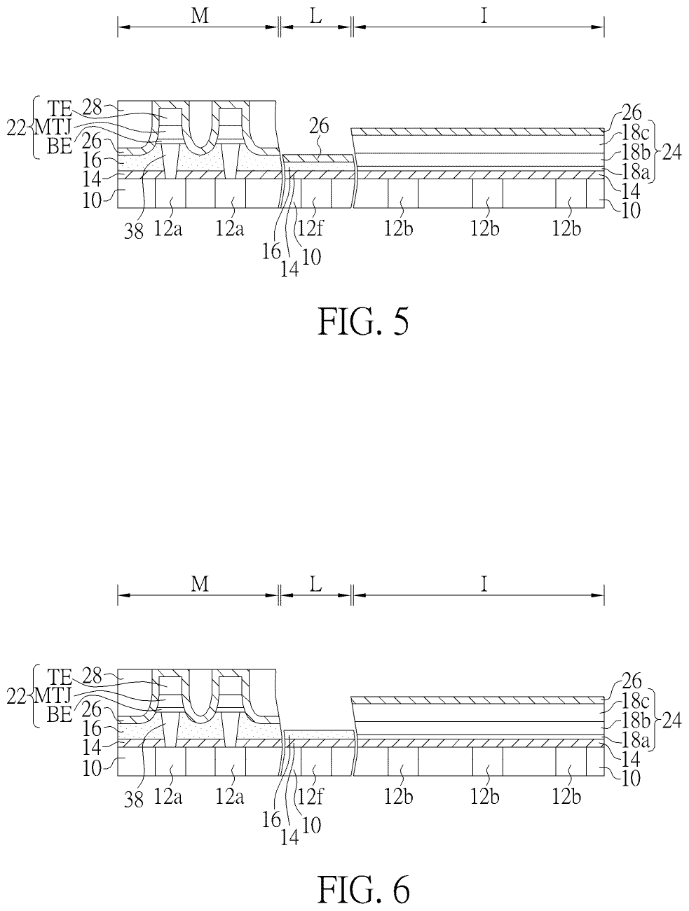

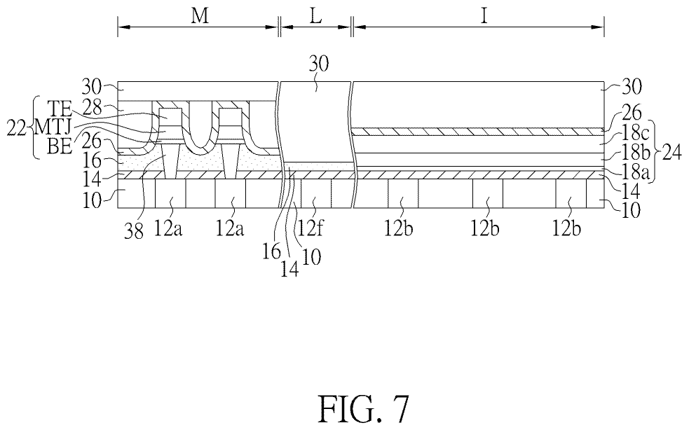

As shown in FIG. 5, a second silicon oxide layer 28 is blankly formed to cover the memory region M, the logic circuit region L and the inductor region I. Later, the second silicon oxide layer 28 is planarized by a chemical mechanical polishing process. Next, the second silicon oxide layer 28 in the logic circuit region L and the inductor region I is completely removed, only the second silicon oxide layer 28 in the memory region M is left to cover the cap layer 26. The second silicon oxide layer 28 and the cap layer 26 are aligned. As shown in FIG. 6, the cap layer 26 in the logic circuit region L is completely removed. As shown in FIG. 7, a second dielectric layer 30 is formed to cover the memory region M, the logic circuit region L and the inductor region I. An entirety of the second dielectric layer 30 is formed by the same deposition process, and the entirety of the second dielectric layer 30 is formed by the same material.

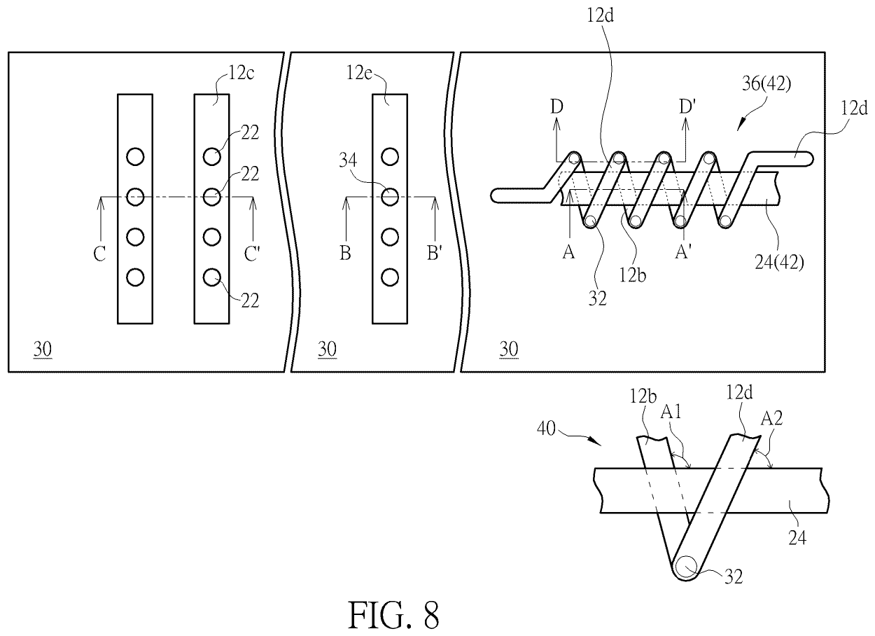

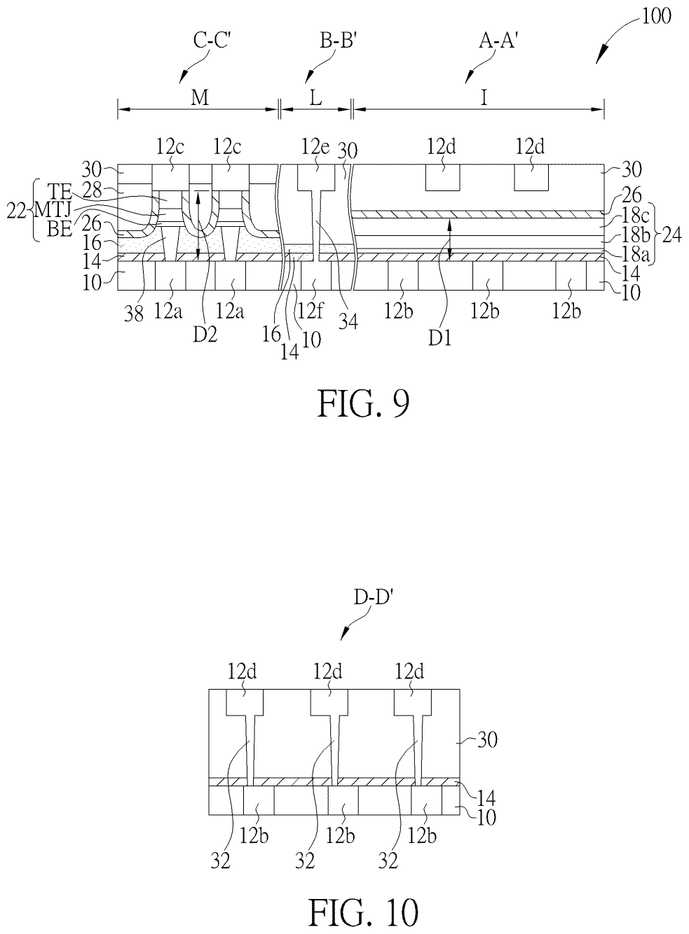

FIG. 8 depicts fabricating steps in continuous of fabricating steps of FIG. 7. FIG. 9 depicts sectional views taken along lines AA′, BB′ and CC′ in FIG. 8. FIG. 10 depicts a sectional view taken along line DD′ in FIG. 8.

Please refer to FIG. 8, FIG. 9 and FIG. 10. A third metal line 12c, numerous first conductive plugs 32, numerous fourth metal lines 12d, a second conductive plug 34 and a fifth metal line 12e are formed by performing a metal interconnection process. The metal interconnection process includes etching the second dielectric layer 30, the second silicon oxide layer 28, the cap layer 26, the first silicon oxide layer 16 and the etching stop layer 14 to form numerous openings and trenches. Later, metal material fills in the openings and the trenches. The third metal line 12c is embedded in the second dielectric layer 30. The third metal line 12c is disposed on the MRAM 22 and contacts the top electrode TE of the MRAM 22. The fifth metal line 12e and the second conductive plug 34 are embedded in the second dielectric layer 30 in the logic circuit region L. The fifth metal line 12e is disposed on the second conductive plug 34, and the fifth metal line 12e contacts the second conductive plug 34. The second conductive plug 34 contacts the sixth metal line 12f. The fourth metal line 12d is embedded in the second dielectric layer 30 and is located on the magnetic core 24. The first conductive plug 32 is disposed between the fourth metal line 12d and the second metal line 12b. One first conductive plug 32 contacts one of the fourth metal lines 12d and one of the second metal lines 12b. Two ends of one of the fourth metal lines 12d respectively have one first conductive plug 32 disposed thereon. Two ends of one of second metal lines 12b respectively have one first conductive plug 32 disposed thereon. All the fourth metal lines 12d and all the second metal lines 12b are electrically connected through the first conductive plugs 32. All the second metal lines 12b, all the fourth metal lines 12d and all the first conductive plugs 32 form a spiral inductor 36 surrounding the magnetic core 24. Furthermore, when seeing from a top view, the first conductive plugs 32 are respectively located on opposite sides of the magnetic core 24. Now, a structure 100 with an MRAM and an inductor of the present invention is completed.

Please refer to FIG. 8, FIG. 9 and FIG. 10. A structure 100 with an MRAM and an inductor includes a dielectric layer 10. The first dielectric layer 10 includes a memory region M, a logic circuit region L and an inductor region I. An etching stop layer 14 is disposed in the memory region M, the logic circuit region L and the inductor region I. The etching stop layer 14 covers and contacts the first dielectric layer 10. The first silicon oxide layer 16 is disposed in the memory region M and the logic circuit region L. The first silicon oxide layer 16 covers and contacts the etching stop layer 14

A second dielectric layer 30 covers the first dielectric layer 10, and a first metal line 12a is embedded in the memory region M of the first dielectric layer 10. A sixth metal line 12f is embedded in the logic circuit region L of the first dielectric layer 10. Numerous second metal lines 12b are embedded in the inductor region I of the first dielectric layer 10. An MRAM 22 is disposed between the second dielectric layer 30 and the first dielectric layer 10. The MRAM 22 is located in the memory region M. The MRAM 22 includes a bottom electrode BE, a magnetic tunnel junction MTJ and a top electrode TE stacked in sequence from bottom to top. A plug 38 is disposed below the MRAM 22, wherein the plug 38 is embedded in the first silicon oxide layer 16 and the etching stop layer 14. The plug 38 contacts the MRAM 22 and first metal line 12a.

A magnetic core 24 is disposed below the second dielectric layer 30 and covers the second metal line 12b. The material of the magnetic core 24 is the same as the material of the MRAM 22. In details, the magnetic core 24 includes a first material layer 18a, a second material layer 18b and a third material layer 18c stacked in sequence from bottom to top. Material of the first material layer 18a is the same as material of the bottom electrode BE, material of the second material layer 18b is the same as material of the magnetic tunnel junction MTJ, and material of the third material layer 18c is the same as material of the top electrode TE.

Because the first silicon oxide layer 16 is not disposed in the inductor region I, the magnetic core 24 covers and contacts the etching stop layer 14. Moreover, a first distance D1 is disposed between the topmost surface of the magnetic core 24 and a top surface of the first dielectric layer 10, a second distance D2 is disposed between the topmost surface of the MRAM 22 and the top surface of the first dielectric layer 10, and the second distance D2 is greater than the first distance D1.

A third metal line 12c is embedded in the second dielectric layer 30. The third metal line 12c is disposed on the MRAM 22 and contacts the top electrode TE of the MRAM 22. When seeing from a top view, the third metal line 12c is in a shape of a strip. There are numerous MRAMs 22A disposed below and contact the third metal line 12c. Numerous fourth metal lines 12d are embedded in the second dielectric layer 30 and located on the magnetic core 24. The fourth metal lines 12d and the second metal lines 12b are electrically connected through numerous first conductive plugs 32. The second metal lines 12b, the fourth metal lines 12d and the first conductive plugs 32 form a spiral inductor coil 36 surrounding the magnetic core 24. The spiral inductor coil 36 and the magnetic core 24 together form an inductor 42. Moreover, According to a preferred embodiment of the present invention, when seeing from a top view, an extending direction of the long side of the magnetic core 24 is perpendicular to an extending direction of the long side of the third metal line 12c.

Moreover, a second conductive plug 34 is disposed in the logic circuit region L and embedded in the second dielectric layer 30, the first silicon oxide layer 16 and the etching stop layer 14. A fifth metal line 12e is embedded in the second dielectric layer 30. The fifth metal line 12e is disposed on the second conductive plug 34, and the fifth metal line 12e contacts the second conductive plug 34. The second conductive plug 34 also contacts the sixth metal line 12f. In addition, the top surface of the third metal line 12c, the top surface of the fourth metal line 12d, the top surface of the fifth metal line 12e and the top surface of the second dielectric layer 30 are aligned with each other.

The first metal line 12a, the second metal lines 12b, the third metal line 12c, the fourth metal lines 12d, the fifth metal line 12e, the sixth metal line 12f, the first conductive plugs 32, the second conductive plug 34 and the plug 38 may respectively include conductive materials such as copper, titanium nitride, titanium, aluminum, tungsten, or other conductive materials. According to a preferred embodiment of the present invention, first metal line 12a, the second metal lines 12b, the third metal line 12c, the fourth metal lines 12d, the fifth metal line 12e, the sixth metal line 12f, the first conductive plugs 32, the second conductive plug 34 all preferably include copper and titanium nitride. The plug 38 preferably includes tungsten.

As shown in the partial enlarged region 40 in FIG. 8, when seeing from a top view, a sidewall of the magnetic core 24 and a sidewall the second metal line 12b form a first angle A1. The sidewall of the magnetic core 24 and a sidewall of the fourth metal line 12d form a second angle A2. The first angle A1 is M degrees by measuring in a counterclockwise direction, and 90≤M<180. The second angle is N degrees by measuring in a counterclockwise direction, and 0<N≤90.

The present invention specifically removes the first silicon oxide layer 16 in the inductor region I so that the distance between the magnetic core 24 and the first dielectric layer 10 becomes smaller. In this way, the vertical height of the inductor 42 can be reduced. In addition, the top electrode TE of the MRAM 22 contacts the third metal line 12c, therefore a conventional conductive plug is omitted. As a result, the third metal line 12c, the electrical spiral inductor coil 36 and the fifth metal layer 12e on the MRAM 22 are in the same dielectric layer (the second dielectric layer 30), thereby reducing the thickness of the component.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A structure with a magnetoresistive random access memory (MRAM) and an inductor, comprising:
a first dielectric layer, wherein the first dielectric layer comprises a memory region and an inductor region;
a second dielectric layer covering the first dielectric layer;
a first metal line embedded within the memory region of the first dielectric layer;
a plurality of second metal lines embedded within the inductor region of the first dielectric layer;
an MRAM disposed between the second dielectric layer and the first dielectric layer, and the MRAM being disposed in the memory region;
a magnetic core disposed below the second dielectric layer and covering the plurality of second metal lines, wherein material of the magnetic core is the same as material of the MRAM, a first distance is disposed between the topmost surface of the magnetic core and a top surface of the first dielectric layer, a second distance is disposed between the topmost surface of the MRAM and the top surface of the first dielectric layer, and the second distance is greater than the first distance;
a third metal line embedded in the second dielectric layer, wherein the third metal line is disposed on and contacts the MRAM; and
a plurality of fourth metal lines embedded in the second dielectric layer and being disposed on the magnetic core, wherein the plurality of fourth metal lines and the plurality of second metal lines are electrically connected through a plurality of first conductive plugs, the plurality of second metal lines, the plurality of fourth metal lines and the plurality of first conductive plugs form an inductor coil surrounding the magnetic core.

2. The structure with an MRAM and an inductor of claim 1, wherein a top surface of the third metal line, a top surface of each of the plurality fourth metal lines and a top surface of the second dielectric layer are aligned.

3. The structure with an MRAM and an inductor of claim 1, further comprising:
an etching stop layer disposed in the memory region and the inductor region, wherein the etching stop layer covers and contacts the first dielectric layer;
a silicon oxide layer disposed in the memory region and covering and contacting the etching stop layer, wherein the magnetic core covers and contacts the etching stop layer;
a plug disposed below the MRAM, wherein the plug is embedded in the silicon oxide layer and the etching stop layer, and the plug contacts the MRAM and the first metal line.

4. The structure with an MRAM and an inductor of claim 3, wherein there is no silicon oxide layer in the inductor region.

5. The structure with an MRAM and an inductor of claim 3, wherein the first dielectric layer further comprises a logic circuit region, the etching stop layer is disposed in the logic circuit region and covers and contacts the first dielectric layer, the silicon oxide layer is disposed in the logic circuit region and covers and contacts the etching stop layer, the second dielectric layer is disposed in the logic circuit region and covers and contacts the silicon oxide layer, the topmost surface of the silicon oxide layer disposed within the logic circuit region is lower than the topmost surface of the silicon oxide layer disposed within the memory region.

6. The structure with an MRAM and an inductor of claim 5, further comprising:
a second conductive plug disposed in the logic circuit region and embedded in the second dielectric layer, the silicon oxide layer and the etching stop layer; and
a fifth metal line embedded in the second dielectric layer, wherein the fifth metal line is disposed on the second conductive plug, and the fifth metal line contacts the second conductive plug.

7. The structure with an MRAM and an inductor of claim 1, wherein the MRAM comprises a bottom electrode, a magnetic tunneling junction (MTJ) and a top electrode stacked in sequence from bottom to top, the magnetic core comprises a first material layer, a second material layer and a third material layer stacked in sequence from bottom to top, and wherein material of the first material layer is the same as material of the bottom electrode, material of the second material layer is the same as material of the MTJ, and material of the third material layer is the same as material of the top electrode.

8. The structure with an MRAM and an inductor of claim 1, wherein when seeing from a top view, a sidewall of the magnetic core and a sidewall of each of the plurality of second metal lines form a first angle, the sidewall of the magnetic core and a sidewall of each of the plurality of fourth metal lines form a second angle, the first angle is M degrees, and the second angle is N degrees, 90≤M<180 and 0<N≤90.

9. The The structure with an MRAM and an inductor of claim 1, wherein when seeing from a top view, the third metal line is in a shape of a strip.

10. A fabricating method of a structure with a magnetoresistive random access memory (MRAM) and an inductor, comprising:
providing a first dielectric layer, wherein the first dielectric layer comprises a memory region and an inductor region, a first metal line is embedded in the memory region of the first dielectric layer, and a plurality of second metal lines are embedded in the inductor region of the first dielectric layer;
forming an etching stop layer and a first silicon oxide layer sequentially to cover the memory region and the inductor region of the first dielectric layer;
completely removing the first silicon oxide layer located in the inductor region;
forming an MRAM material layer covering and contacting the first silicon oxide layer in the memory region and covering and contacting the etching stop layer in the inductor region;
patterning the MRAM material layer to form an MRAM and a magnetic core, wherein the MRAM is disposed in the memory region and the magnetic core is disposed in the inductor region;
forming a second dielectric layer to cover the memory region and the inductor region; and
performing a metal interconnection process to form a third metal line, a plurality of first conductive plugs and a plurality of fourth metal lines, wherein the third metal line is embedded in the second dielectric layer, disposed on the MRAM and in contact with the MRAM, the plurality of fourth metal lines are embedded in the second dielectric layer and disposed on the magnetic core, the plurality of first conductive plugs are disposed between the plurality of fourth metal lines and the plurality of second metal lines, the plurality of fourth metal lines and the plurality of second metal lines are electrically connected through the plurality of first conductive plugs, and the plurality of second metal lines, the plurality of fourth metal lines and the plurality of first conductive plugs form an inductor coil surrounding the magnetic core.

11. The fabricating method of a structure with an MRAM and an inductor of claim 10, wherein the first dielectric layer further comprising a logic circuit region, when forming the etching stop layer and the first silicon oxide layer, the etching stop layer and the first silicon oxide layer are also formed in the logic circuit region.

12. The fabricating method of a structure with an MRAM and an inductor of claim 11, further comprising:
when patterning the MRAM material layer, simultaneously removing a part of the first silicon oxide layer to make the topmost surface of the first silicon oxide layer located in the logic circuit region is lower than the topmost surface of the first silicon oxide layer located in the memory region;
after patterning the MRAM material layer, forming a cap layer to cover the MRAM, the logic circuit region and the magnetic core;
removing the cap layer in the logic circuit region;
forming a second silicon oxide layer to cover only the memory region;
after forming the second silicon oxide layer, forming the second dielectric layer; and
performing the metal interconnection process to form a second conductive plug and a fifth metal line simultaneously, wherein the second conductive plug is disposed in the logic circuit region and embedded in the second dielectric layer, the silicon oxide layer and the etching stop layer, and wherein the fifth metal line is embedded in the second dielectric layer, the fifth metal line is disposed on the second conductive plug, and the fifth metal line contacts the second conductive plug.

13. The fabricating method of a structure with an MRAM and an inductor of claim 10, wherein the MRAM material layer comprises a bottom electrode, a magnetic tunneling junction (MTJ) and a top electrode stacked in sequence from bottom to top.

14. The fabricating method of a structure with an MRAM and an inductor of claim 10, wherein when seeing from a top view, a sidewall of the magnetic core and a sidewall of each of the plurality of second metal lines form a first angle, the sidewall of the magnetic core and a sidewall of each of the plurality of fourth metal lines form a second angle, the first angle is M degrees, and the second angle is N degrees, 90≤M<180 and 0<N≤90.

15. The fabricating method of a structure with an MRAM and an inductor of claim 10, wherein when seeing from a top view, the plurality of first conductive plugs are respectively disposed on opposite sides of the magnetic core.

16. The fabricating method of a structure with an MRAM and an inductor of claim 10, wherein when seeing from a top view, the third metal line is in a shape of a strip.

17. The fabricating method of a structure with an MRAM and an inductor of claim 10, wherein a top surface of the third metal line, a top surface of each of the plurality of fourth metal lines and a top surface of the second dielectric layer are aligned.
